(19) United States
(12) Patent Application Publication
(10) Pub. No.: US 2024/0201294 A1
(43) Pub. Date: Jun. 20, 2024

(54) INFORMATION PROCESSING APPARATUS, MAGNETIC RESONANCE IMAGING APPARATUS, INFORMATION PROCESSING METHOD, AND STORAGE MEDIUM

(71) Applicants: CANON KABUSHIKI KAISHA, Tokyo (JP); CANON MEDICAL SYSTEMS CORPORATION, Tochigi (JP)

(72) Inventors: Mitsuaki AMEMIYA, Saitama (JP); Hiromi KINEBUCHI, Kanagawa (JP); Naoya IIZUKA, Kanagawa (JP)

(21) Appl. No.: 18/531,878

(22) Filed: Dec. 7, 2023

(30) Foreign Application Priority Data
Dec. 15, 2022 (JP) 2022-200509

(51) Int. Cl. G01R 33/385; G01R 33/54

(52) U.S. Cl. CPC G01R 33/3854; G01R 33/546

(57) ABSTRACT

An information processing apparatus includes: a selection unit configured to select a learning result that corresponds to operation information or an operation sound of a magnetic resonance imaging apparatus; and an estimation unit configured to estimate audio for which the operation sound has been reduced in operation-sound-included audio in which the operation sound and audio of a subject are overlapped, using the learning result.

### BACKGROUND OF THE INVENTION

### Field of the Invention

The present invention relates to an information processing apparatus, a magnetic resonance imaging apparatus, an information processing method, and a storage medium.

### Description of the Related Art

In examinations in which a magnetic resonance imaging apparatus is used, imaging is performed by processing signals, which have been obtained by creating a gradient magnetic field, which varies depending on the imaging position and the like; however, the variation in the gradient magnetic field causes the apparatus to vibrate, which may thus generate operation sounds. Japanese Patent Laid-Open No. 2002-132289 discloses a method of reducing noise that has been classified in advance.

When a subject and an operator communicate by speech and the like during an examination, if audio of the subject overlaps the operation sounds, it will be difficult for the operator to hear the audio of the subject, and thus, cases where the subject cannot smoothly communicate with the operator may occur.

The present invention provides a technique that makes it possible to reduce an operation sound in operation-sound-included audio in which the operation sound and audio of a subject are overlapped.

### SUMMARY OF THE INVENTION

According to one aspect of the present invention, there is provided an information processing apparatus comprising: a selection unit configured to select a learning result that corresponds to operation information or an operation sound of a magnetic resonance imaging apparatus; and an estimation unit configured to estimate audio for which the operation sound has been reduced in operation-sound-included audio in which the operation sound and audio of a subject are overlapped, using the learning result.

Further features of the present invention will become apparent from the following description of exemplary embodiments with reference to the attached drawings.

### BRIEF DESCRIPTION OF THE DRAWINGS

FIG. 1 is a block diagram illustrating a schematic configuration of a magnetic resonance imaging apparatus according to a first embodiment.

FIGS. 2A to 2C are diagrams illustrating a flow of processes by an information processing apparatus according to the first embodiment.

FIG. 3 is a diagram illustrating operation sounds to be used in learning processing.

FIG. 4 illustrates operation sounds to be used in evaluation processing.

FIG. 5 is a diagram for schematically explaining volume adjustment and synthesized audio generation processing.

FIG. 6 is a diagram schematically illustrating processing for dividing a class of operation sounds.

FIG. 7 is a diagram schematically illustrating processing for grouping classes of operation sounds corresponding to a plurality of pieces of operation information into one.

FIG. 8 is a diagram schematically illustrating a new operation sound, which has been generated using a random number.

FIG. 9 is a diagram illustrating a signal of operation-sound-included audio, and a diagram illustrating a signal of operation-sound-reduced audio.

FIG. 10 is a diagram schematically illustrating a correspondence between classes that are based on operation information and optimal conversion information (learning results).

FIG. 11 is a diagram illustrating a flow of processing in a seventh embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

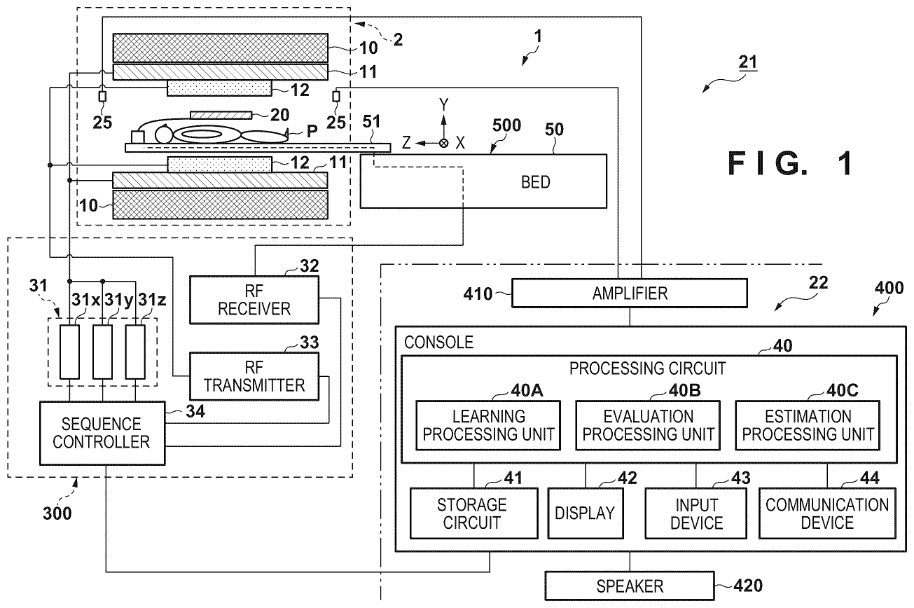

FIG. 1 is a block diagram illustrating an overall configuration of a magnetic resonance imaging apparatus 1 (hereinafter, also referred to as “MRI apparatus”) according to a first embodiment. The magnetic resonance imaging apparatus 1 of the first embodiment is configured to include a magnet frame 2, a control cabinet 300, a console 400, a bed 500, and the like. The magnetic resonance imaging apparatus 1 is placed in an examination room 21 in which examinations are performed, and an operator can operate the magnetic resonance imaging apparatus 1 in an operation room 22, which is separated from the examination room 21.

The magnet frame 2 includes a static magnetic field magnet 10, a gradient magnetic field coil 11, a whole body (WB) coil 12, and the like, and these components are housed in a cylindrical tube-shaped housing. The bed 500 includes a bed main body 50 and a top plate 51. The magnetic resonance imaging apparatus 1 also includes a local coil 20, which is disposed in close proximity to a subject P.

The control cabinet 300 includes gradient magnetic field power supplies 31 (31x for x-axis, 31y for y-axis, and 31z for z-axis), an RF receiver 32, an RF transmitter 33, and a sequence controller 34.

The static magnetic field magnet 10 of the magnet frame 2 has a substantially cylindrical tubular shape and generates a static magnetic field in the bore (space on the inside of the cylindrical tube of the static magnetic field magnet 10), which is an imaging region of the subject P (e.g., patient). The gradient magnetic field coil 11 also has a substantially cylindrical tubular shape and is fixed on the inner side of the static magnetic field magnet 10. The gradient magnetic field coil 11 has a three-channel structure. A current is supplied respectively from the gradient magnetic field power supplies (31x, 31y, and 31z) to the gradient magnetic field coils of respective channels of the gradient magnetic field coil 11, and a gradient magnetic field is generated in the respective x-axis, y-axis, and z-axis directions.

The bed main body 50 of the bed 500 can move the top plate 51 in a vertical direction (Y direction) and, before imaging, moves the subject P, who is on the top plate 51, to a predetermined height. Then, at the time of imaging, the bed main body 50 moves the subject P into the bore by moving the top plate 51 in a horizontal direction (Z direction).

The WB coil 12 is fixed in a substantially cylindrical tubular shape so as to enclose the subject P on the inner side of the gradient magnetic field coil 11. The WB coil 12, on the one hand, transmits an RF pulse transmitted from the RF transmitter 33 to the subject P and, on the other hand, receives a magnetic resonance signal (i.e., MR signal) emitted from the subject P by excitation of hydrogen nuclei.

The local coil 20 receives an MR signal emitted from the subject P at a position close to the subject P. The local coil 20 is constituted by, for example, a plurality of component coils. The local coil 20 may be of various types, such as for the head, the chest, the spine, the lower limbs, or the whole body depending on the imaging part of the subject P; however, FIG. 1 illustrates a local coil 20 for the chest. A cable for passing a received signal is connected to the local coil 20 and a connector of the top plate. In addition, from the connector of the top plate, a cable is further connected from the top plate to the bed and the RF receiver 32, and an analog signal received by the local coil 20 is passed through these cables and outputted to the RF receiver 32. The present invention can be applied even if the local coil 20 is made fully wireless without cable connection.

The RF transmitter 33 transmits an RF pulse to the WB coil 12 based on an instruction from the sequence controller 34. Meanwhile, the RF receiver 32 receives an MR signal received by the WB coil 12 and the local coil 20, performs amplification, detection, digitalization, and filtering processing on the MR signal, and transmits raw data to the sequence controller 34.

The sequence controller 34 scans the subject P by driving each of the gradient magnetic field power supplies 31, the RF transmitter 33, and the RF receiver 32 under the control of the console 400 (information processing apparatus). Then, upon performing scanning and receiving raw data from the RF receiver 32, the sequence controller 34 transmits that raw data to the console 400.

The sequence controller 34 includes a processing circuit (not illustrated). The processing circuit is configured by hardware, such as a processor for executing a predetermined program, a field programmable gate array (FPGA), and application specific integrated circuit (ASIC).

Microphones 25 (sound collecting apparatuses) are provided in the housing of the magnetic resonance imaging apparatus 1 and collect audio signals. The microphone 25 is provided at two positions, on one end side (Z+ side) and the other end side (Z-side) of the housing. During an examination of the subject P, the microphones 25 collect an operation sound of the magnetic resonance imaging apparatus 1, and audio of the subject P is collected as audio (operation-sound-included audio) in which it is overlapped on the operation sound of the magnetic resonance imaging apparatus 1. An amplifier 410 inputs the audio signals collected by the microphones 25 to a processing circuit 40. In the processing circuit 40, audio (operation-sound-reduced audio) for which the operation sound has been reduced in the operation-sound-included audio is generated. A speaker 420 (audio output apparatus) outputs the operation-sound-reduced audio generated by the processing circuit 40.

The console 400 is configured as a computer (information processing apparatus) that includes the processing circuit 40, a storage circuit 41, a display 42, an input device 43 and a communication device 44.

The storage circuit 41 is a storage medium that includes not only a read only memory (ROM) and a random access memory (RAM) for storing various kinds of information but also an external storage apparatus, such as a hard disk drive (HDD), a solid state drive (SSD), and an optical disk apparatus. The storage circuit 41 not only stores various kinds of information and data, such as data collection conditions and MR images but also stores various kinds of programs to be executed by the processor included in the processing circuit 40.

The display 42 is a display device, such as a liquid crystal display panel, a plasma display panel, and an organic EL panel. The input device 43 includes various kinds of input devices for receiving various kinds of commands from the operator. The input device 43 is, for example, a mouse, a keyboard, a trackball, and a touch panel, and includes various kinds of devices for the operator to input various kinds of information and data. The input device 43 is not limited only to those that include physical operation components, such as a mouse and a keyboard. For example, the input device 43 may be a signal conversion apparatus (interface) that converts a signal of the audio of the subject P outputted from the amplifier 410 into a signal for processing in the processing circuit 40 and converts the signal processed in the processing circuit 40 into a signal for outputting to the speaker 420 (audio output apparatus).

The communication device 44 is an interface that connects the magnetic resonance imaging apparatus 1 and other external apparatuses, such as a workstation, a picture archiving and communication system (PACS), a hospital information system (HIS), and a radiology information system (RIS) via a local area network (LAN) and the like. The communication device 44 transmits and receives various kinds of information to and from connection destination workstation, PACS, HIS and RIS.

The processing circuit 40 is a circuit that includes, for example, a central processing unit (CPU) and a dedicated or general-purpose processor. The processor realizes various kinds of functions, which will be described later, by executing various kinds of programs stored in the storage circuit 41. The processing circuit 40 may be configured by hardware, such as field programmable gate array (FPGA) and an application specific integrated circuit (ASIC). The processing circuit 40 may be configured by a single processor or a combination of a plurality of independent processors. In the latter case, the storage circuit 41, which stores programs, may be provided individually for each of the plurality of processors, or a single storage circuit 41 may store programs corresponding to the functions of the plurality of processors. The various kinds of functions, which will be described later, can also be realized by these pieces of hardware. The processing circuit 40 can also realize the various kinds of functions by combining software processing by the processor and programs and hardware processing.

The processing circuit 40 includes a learning processing unit 40A, an evaluation processing unit 40B, and an estimation processing unit 40C, which are realized by executing respective programs. The learning processing unit 40A, the evaluation processing unit 40B, and the estimation processing unit 40C are functional components obtained by the processor of the processing circuit 40 executing respective programs. Information necessary for execution of processes to be realized by the respective functions and information obtained in the middle and end of processes are stored in the storage circuit 41. The configuration of the processing circuit 40 illustrated in FIG. 1 is only an example. For example, each component in the processing circuit 40 may be configured separately as appropriate. For example, the components of the processing circuit 40 may be performed by a processor of the sequence controller 34.

The learning processing unit 40A uses audio (clean audio) of a subject and an operation sound of the magnetic resonance imaging apparatus 1, which are prepared in advance, to generate operation-sound-included audio for learning in which the audio of the subject is overlapped on the operation sound and obtains conversion coefficients (hereinafter conversion information) for converting the operation-sound-included audio for learning into the clean audio. Regarding input data of machine learning, the learning processing unit 40A uses, as problem data, audio (operation-sound-included audio) in which the operation sound of the magnetic resonance imaging apparatus 1 and the audio (clean audio) of the subject are overlapped and uses, as ground truth data, the audio (clean audio) of the subject. In addition, the learning processing unit 40A obtains, as output data of machine learning, a learning model (hereinafter, also referred to as “computation model”) that outputs conversion information for converting problem data (operation-sound-included audio) into ground truth data (clean audio). The learning processing unit 40A obtains a plurality of learning models (computation models) for which machine learning has been performed under different computation conditions.

The evaluation processing unit 40B performs processing for obtaining optimal conversion information from among a plurality of pieces of conversion information according to a plurality of computation conditions. The evaluation processing unit 40B calculates evaluation information (signal distortion rate (SDR)), which will be described later, using the audio (clean audio) of the subject and the operation sound of the magnetic resonance imaging apparatus 1 and selects optimal conversion information (optimal learning result: first learning result) from among a plurality of pieces of conversion information (plurality of learning results) based on the calculated evaluation information. Here, the optimal conversion information (optimal learning result: first learning result) can be referred to as an optimal learning model. The evaluation processing unit 40B may select an optimal learning model (first learning model) from among a plurality of learning models based on the calculated evaluation information.

The estimation processing unit 40C performs processing for reducing the operation sound from the operation-sound-included audio in an actual examination in which the magnetic resonance imaging apparatus 1 is used. The estimation processing unit 40C selects the optimal conversion information (optimal learning result: first learning result), which corresponds to the operation sound or operation information of the magnetic resonance imaging apparatus 1, at the time of examination. That is, the optimal conversion information (optimal learning result: first learning result) corresponds to the operation sound or operation information of the magnetic resonance imaging apparatus 1. The optimal learning model (first learning model) can also be said to correspond to the operation sound or operation information of the magnetic resonance imaging apparatus 1. The estimation processing unit 40C estimates audio for which the operation sound has been reduced in the operation-sound-included audio, which has been collected by the microphones 25 and in which the operation sound of the magnetic resonance imaging apparatus and the audio of the subject are overlapped, using the selected optimal conversion information (learning result).

In the present embodiment, the operation information of the magnetic resonance imaging apparatus 1 may be one or a combination of (a) information indicating the type of various kinds of imaging in the MRI apparatus (e.g., T1-weighted, T2-weighted, proton density (PD), and diffusion weighted imaging (DWI)), (b) information indicating the type of an MR signal collection method (e.g., parallel imaging (PI), echo planar imaging (EPI), radial collection, and spiral collection), (c) a pulse sequence, which is a pulse waveform output plan for collecting an MR signal, and (d) a hardware control signal for executing a pulse sequence. Even if the operation is based on the same operation information, detailed settings, such as a pulse frequency and a magnetic field direction, need to be performed, and the operation sound of the magnetic resonance imaging apparatus 1 is different depending on the settings.

In the present embodiment, a flowchart of computation to be performed by respective functional components (the learning processing unit 40A, the evaluation processing unit 40B, and the estimation processing unit 40C) of the processing circuit 40 includes three processes, which are learning processing, evaluation processing, and estimation processing.

In a processing flow of the present embodiment, deep learning is used after the clean audio and the operation-sound-included audio are converted into power spectra as an example of a process for comparing the operation-sound-included audio and audio (clean audio) for which a period in which there is no audio has been removed from the recorded audio of the subject or a process for removing the operation sound from the operation-sound-included audio. The present invention is not limited to this processing method, and another method may be used. For example, a method of comparing waveforms of the clean audio and the operation-sound-included audio, directly with deep learning, may be used.

### (Learning Processing)

The learning processing unit 40A uses audio (clean audio) of a subject and an operation sound (recorded operation sound) of the magnetic resonance imaging apparatus 1 to generate operation-sound-included audio for learning in which the audio of the subject is overlapped on the operation sound, and obtains conversion information for converting the operation-sound-included audio for learning into the clean audio.

First, the learning processing unit 40A generates (step S101) clean audio, for which a period in which there is no audio has been removed, from various databases or audio data (audio file) for which audio of the subject has actually been recorded.

The learning processing unit 40A divides (performs frame division on) (step S102) the clean audio into fixed unit time periods and converts (step S103) the divided clean audio into power spectra, using fast Fourier transform (FFT).

Next, the learning processing unit 40A synthesizes, from the clean audio (step S101) and the operation sound, operation-sound-included audio.

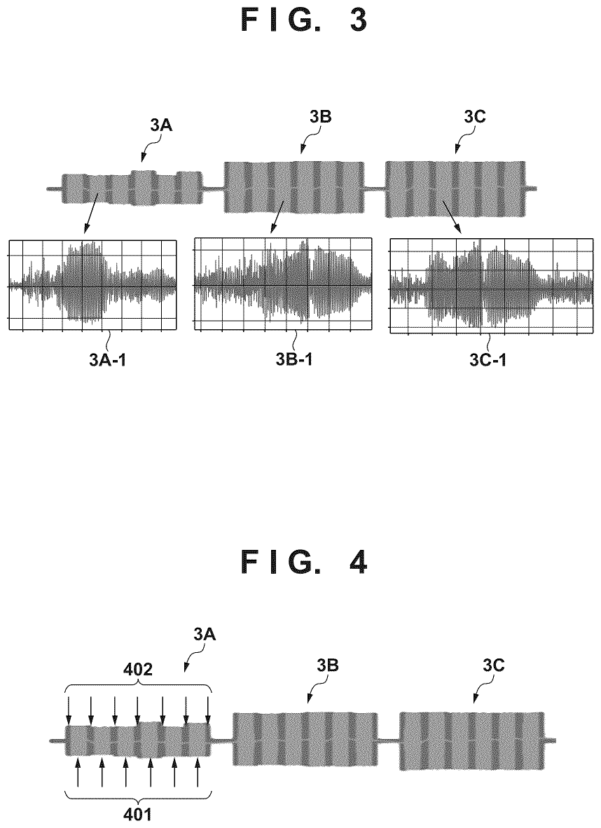

In step S104, the magnetic resonance imaging apparatus 1 is operated at settings that are based on one piece of operation information, and the operation sound is recorded for each setting. The magnetic resonance imaging apparatus 1 is operated at settings that are based on a variety of operation information, the operation sound is recorded for each setting, and the operation sounds are classified based on the variety of operation information (step S105). For example, as illustrated in FIG. 3, for one piece of operation information, operation sounds 3A, 3B, and 3C are recorded respectively for three different settings and classified as operation sounds (3A to 3C) corresponding to the operation information.

A variety of operation sounds may be generated by changing various kinds of settings in the operation information, such as variables related to a pulse, such as frequency and direction, in the magnetic resonance imaging apparatus 1, or different operation sounds may be generated using a wave reflected by an audio reflector. The learning processing unit 40A generates an operation sound for learning for which a silent portion has been removed from the operation sound thus recorded (step S106).

In step S107, the learning processing unit 40A generates the operation-sound-included audio for learning by synthesizing the clean audio (step S101) and the operation sound for learning generated in step S106.

In step S200, the learning processing unit 40A extracts features of the operation-sound-included audio for learning. The feature extraction processing includes steps from operation-sound-included audio frame division (step S102) to power spectrum generation (step S110).

The frame division of step S102 is similar processing to that of the frame division of the clean audio, and the learning processing unit 40A divides the operation-sound-included audio into fixed unit time periods. Then, the learning processing unit 40A converts the frame-divided operation-sound-included audio into power spectra by Fourier transform and generates a spectrogram in which the converted power spectra are arranged in a time series (step S108).

The spectrogram is two-dimensional data that has two variables, which are time and frequency, and the learning processing unit 40A performs data processing called deep learning (DL) (step S109), which will be described later, and converts the spectrogram, which is two-dimensional data, into a one-dimensional power spectrum (step S110).

In the feature extraction processing (step S200) according to the present embodiment, the operation-sound-included audio is converted into a spectrogram, and then data processing called deep learning (DL) is performed. Here, deep learning is a computation technique that uses multiple layers of a neural network, which is a system that resembles the mechanism of human nerve cells (neurons), and is a method of obtaining information for converting the operation-sound-included audio into the operation-sound-reduced audio by repeatedly performing computation so as to reduce a difference between the power spectrum that has been computed from the spectrogram of the operation-sound-included audio and the power spectrum of the clean audio.

There is a variety of methods of data processing in deep learning. For example, “A Fully Convolutional Neural Network for Speech Enhancement” (https://arxiv.org/abs/1609.07132) discloses data processing in which convolution-based deep learning computation model (redundant convolutional encoder-decoder (hereinafter, “R-CED model”)) is used. In the R-CED model, a two-dimensional spectrogram whose variables are time and frequency is convolved with a plurality of two-dimensional filters to which weighting coefficients have been assigned, and the spectrogram is converted into a one-dimensional power spectrum that only has frequency as the variable. Here the number of power spectra outputted is the number of filters.

Next, the plurality of power spectra obtained by convolution are convolved with a plurality of one-dimensional filters by multiplying them with weighting coefficients. The weighting coefficients and the shape and number of filters are changed and the conversion into a plurality of power spectra is repeated. Assuming that convolution is one layer, after convolution computation is performed for a predetermined number of layers, in the end, conversion to one power spectrum is performed with one filter.

Evaluation for which a difference between the power spectrum of the spectrogram obtained last and the power spectrum of the clean audio is reduced for a combination (data set) of all operation sounds and clean audio is performed. For example, the coefficients are changed so as to reduce an evaluation value such as a least square error, and convolution is repeated for computation of a predetermined number of layers, and thus conversion information constituted by a series of coefficients is obtained. The number of epochs is the number of times of iterative computation, and when the number of epochs is increased, an evaluation function decreases for the dataset used in learning. However, the evaluation function does not necessarily improve for an operation sound and audio that have not been learned, and there are an optimal number of epochs for each operation sound. In the present embodiment, it is assumed that, by iterative computation, the optimal number of epochs for reducing an output of the evaluation function for a respective operation sound is obtained and the learning processing is performed.

There are a variety of methods in deep learning. The previously-described method of repeating convolution is called a convolutional neural network (CNN). In addition, there are deep neural networks (DNNs), recurrent neural networks (RNNs), generative adversarial networks (GANS), and the like, and any method can be applied to the feature extraction processing of the present embodiment.

In addition, the feature extraction processing (step S200) can also be performed without converting audio into a spectrogram. For example, it is possible to directly compare the waveforms of the frame-divided operation-sound-included audio and the clean audio and obtain the information for converting the operation-sound-included audio into the clean audio by deep learning.

In step S111, the learning processing unit 40A obtains a set of conversion information for which the difference between the power spectrum (step S103) of the clean audio, which is one-dimensional data, and the power spectrum (step S110) for which data processing has been performed on the spectrogram is reduced.

The conversion information changes depending on the data processing method, the sampling frequency, and the time period of the frame; however, for example, several tens to hundreds of thousands of numerical values may be included in the conversion information. At this time, the learning processing unit 40A generates several tens to hundreds of thousands of sets of a combination of a power spectrum 103 of the clean audio and a power spectrum 110 of the spectrogram and changes the conversion information and repeatedly performs computation such that the difference between the power spectrum 103 of the clean audio and the power spectrum 110 of the spectrogram is reduced, generally for any set. The number of times of iterative computation in which learning is performed by iteration of learning data a number of times is called the number of epochs. In the learning processing of the present embodiment, the number of epochs can be arbitrarily set.

FIG. 3 is a diagram exemplarily illustrating operation sounds that are used in learning and illustrates three operation sounds (3A to 3C) of different settings. The horizontal axis indicates time, and the vertical axis indicates frequency. In FIG. 3, a signal waveform 3A-1 is a diagram for which a signal of an operation sound to be used in learning has been enlarged in the operation sound 3A. In addition, a signal waveform 3B-1 is a diagram in which a signal of an operation sound to be used in learning has been enlarged in the operation sound 3B, and a signal waveform 3C-1 is a diagram for which a signal of an operation sound to be used in learning has been enlarged in the operation sound 3C.

When there are three different settings in one piece of operation information, three operation sounds are recorded, and the learning processing unit 40A obtains a set of conversion information for which the difference between the power spectrum (step S110) of the spectrogram and the power spectrum (step S103) of the clean audio is reduced generally for the three operation sounds.

In the learning processing, there are a variety of calculation conditions, such as the intensity ratio between the operation sound for learning and the clean audio at the time of generating the operation-sound-included audio, the number of sets of a combination of the clean audio and the spectrogram, and the number of epochs. Regarding the operation sound used in the learning processing, it is possible to generate conversion information that can reduce operation sounds that correspond to a variety of settings of the operation information by performing learning using operation sounds generated according to a variety of variables of the operation information related to the magnetic resonance imaging apparatus 1.

It is also possible to generate a general-purpose set of conversion information by performing learning collectively for all operation sounds generated from all pieces of operation information. However, when learning is performed collectively for all operation sounds, if a new operation sound appears, for example, learning needs to be performed again from the beginning with the new operation sound added to the existing operation sounds, which is inefficient. Therefore, it is more efficient to separate operation sounds into types of operation sounds that are similar to a certain extent, perform learning, and generate a set of conversion information for each type, and thus, improvement in the performance of operation sound reduction is expected.

Therefore, in the present embodiment, it is assumed that the magnetic resonance imaging apparatus 1 is operated at a plurality of settings included in one piece of operation information of the magnetic resonance imaging apparatus 1 and the operation sound recorded for each setting is used (step S104). Not only the variables related to a pulse, such as frequency and direction of an operation sound, in the magnetic resonance imaging apparatus 1 but also a wave reflected by an audio reflector may be used; learning is performed collectively for operation sounds in units of these pieces of operation information, and a plurality of pieces of conversion information are obtained for each piece of operation information according to a plurality of computation conditions (step S111).

### (Evaluation Processing)

The evaluation processing unit 40B performs processing for obtaining optimal conversion information from among a plurality of pieces of conversion information according to a plurality of computation conditions. The evaluation processing unit 40B selects, for each piece of operation information, conversion information for which the difference between the spectrogram of the operation-sound-included audio and the power spectrum of the clean audio is reduced from among a plurality of pieces of conversion information, which have been obtained by the learning processing and accord with a plurality of computation conditions.

The clean audio of step S101 of the evaluation processing is similar to the clean audio of step S101 of the learning processing. The evaluation processing unit 40B generates clean audio, for which a period in which there is no audio has been removed, from various kinds of databases or audio data for which audio of the subject has actually been recorded.

In step S104′, the evaluation processing unit 40B uses, as an operation sound for evaluation, operation sound regions that are different from operation sound regions used in the learning processing. For example, if the operation sound of regions 401 of FIG. 4 has been used in the learning processing, the operation sound for evaluation may be generated using signals of regions 402 in the evaluation processing. FIG. 4 is only an example, and the operation sound for evaluation need only be different at least in some signals from the operation sound used in the learning processing.

In step S107, the evaluation processing unit 40B generates operation-sound-included audio for evaluation from the operation sound (step S104′) and the clean audio (step S101). The evaluation processing unit 40B generates operation-sound-included audio for evaluation (step S107) by synthesizing the clean audio (step S101) and the operation sound for evaluation (step S104′).

In step S200, the evaluation processing unit 40B extracts features of the operation-sound-included audio for evaluation. The content of the feature extraction processing is similar to that of the learning processing, and the feature extraction processing includes steps from operation-sound-included audio frame division (step S102) to power spectrum generation (step S110).

The evaluation processing unit 40B extracts features of the operation-sound-included audio, using the conversion information obtained by the learning processing (step S200) and obtains the power spectrum (step S110).

In step S122, the evaluation processing unit 40B performs inverse fast Fourier transform (inverse FFT) on the power spectrum obtained in step S110, restores the audio signal for each frame, performs audio re-synthesis in which the restored per-frame audio signals are connected (step S122), and, by audio re-synthesis, generates audio (operation-sound-reduced audio) for which the operation sound has been reduced in the operation-sound-included audio. The evaluation processing unit 40B generates operation-sound-reduced audio, using a plurality of pieces of conversion information, which have been obtained by learning and accord with a variety of computation conditions (step S123). Here, the operation-sound-reduced audio is audio for which the operation sound has been reduced in the operation-sound-included audio for evaluation.

In step S124, the evaluation processing unit 40B obtains evaluation information for evaluating the plurality of pieces of conversion information, using the clean audio (step S101) and the operation-sound-reduced audio (step S123). The evaluation processing unit 40B uses a signal distortion rate (SDR) as evaluation information. Here, the signal distortion rate (SDR) is disclosed in, for example, “Noise-Power Estimation Based on Ratio of Stationary Noise to Input Signal for Noise Reduction” in Journal of Signal Processing (2014, pp. 17), and the evaluation processing unit 40B obtains the signal distortion rate (SDR) based on the following Equation 1 and Equation 2. In the present embodiment, the signal distortion rate (SDR) is used as the evaluation information.

$$SDR = 10 log ( \frac{{\sum }_{k = 0}^{k - 1} {s}^{2} ( {t}_{k} )}{{\sum }_{k = 0}^{k - 1} {\{ s ( {t}_{k} ) - λ \cdot {s}^{′} ( {t}_{k} ) \}}^{2}} ) \qquad [ EQUATION 1 ]$$

$$λ = \sqrt{\frac{{\sum }_{k = 0}^{k - 1} {s}^{2} ( {t}_{k} )}{{\sum }_{k = 0}^{k - 1} {s}^{′2} ( {t}_{k} )}} \qquad [ EQUATION 2 ]$$

The evaluation information (SDR) indicates a distortion between the clean audio (step S101) and the operation-sound-reduced audio (step S123) as given by Equation 1, and the greater the numerical value, the smaller the difference between the operation-sound-reduced audio (step S123) and the clean audio (step S101). Here, s(tₖ) and s′(tₓ) are amplitudes of the clean audio (step S101) and of the operation-sound-reduced audio (step S123), respectively, at time tₖ.

In step S125, the evaluation processing unit 40B selects conversion information (optimal conversion coefficient) for which the difference between the operation-sound-reduced audio (step S123) and the clean audio (step S101) is the smallest based on the evaluation information obtained in step S124. In other words, the evaluation processing unit 40B selects, as a learning result, the conversion information (optimal conversion coefficient) for which the evaluation information (SDR) has the largest value for a variety of computation conditions in each piece of operation information. The optimal conversion coefficient (learning result) selected in this step is used in the following estimation processing.

### (Estimation Processing)

The estimation processing unit 40C performs processing for reducing the operation sound from the operation-sound-included audio in an actual examination in which the magnetic resonance imaging apparatus 1 is used.

The estimation processing unit 40C receives the operation information of the magnetic resonance imaging apparatus 1 and identifies (classifies) the operation information or the operation sound of the current operation in step S131 and selects (step S132) the conversion information (learning result) corresponding to the operation information or the operation sound. The conversion information (learning result) selected in step S132 is based on the conversion information (optimal conversion coefficient) obtained by the evaluation processing.

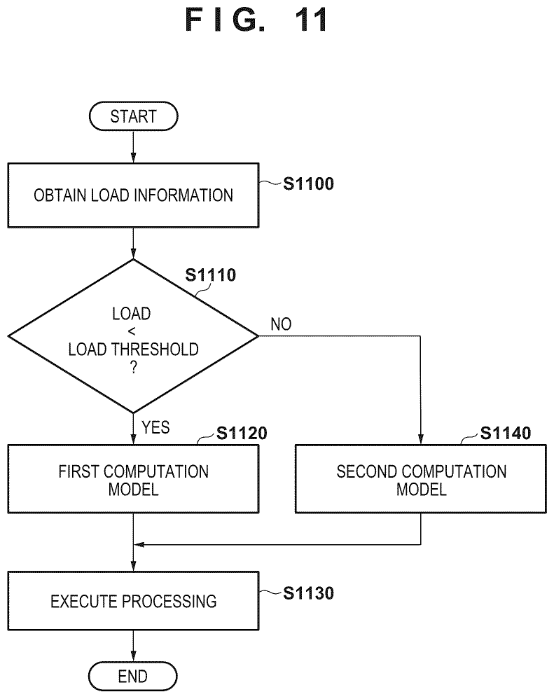

FIG. 10 is a diagram schematically illustrating a correspondence between classes that are based on operation information and optimal conversion information (learning results). Operation sounds 10A to 10C are classified into operation information 1001, and operation sounds 10D and 10E are classified into operation information 1002. In addition, operation sounds 10F to 10J are classified into operation information 1003. Based on the learning processing and the evaluation processing, setting is performed such that optimal conversion information 1004 corresponds to the operation information 1001, optimal conversion information 1005 corresponds to the operation information 1002, and optimal conversion information 1006 corresponds to the operation information 1003.

For example, if operation information is obtained from the magnetic resonance imaging apparatus 1, mid-examination operation information can be identified and corresponding optimal conversion information (learning result) can be obtained. Alternatively, if an operation sound is obtained from the magnetic resonance imaging apparatus 1, which is in the middle of an examination, and a class of operation sounds that have a high correlation can be identified, corresponding optimal conversion information (learning result) can be obtained.

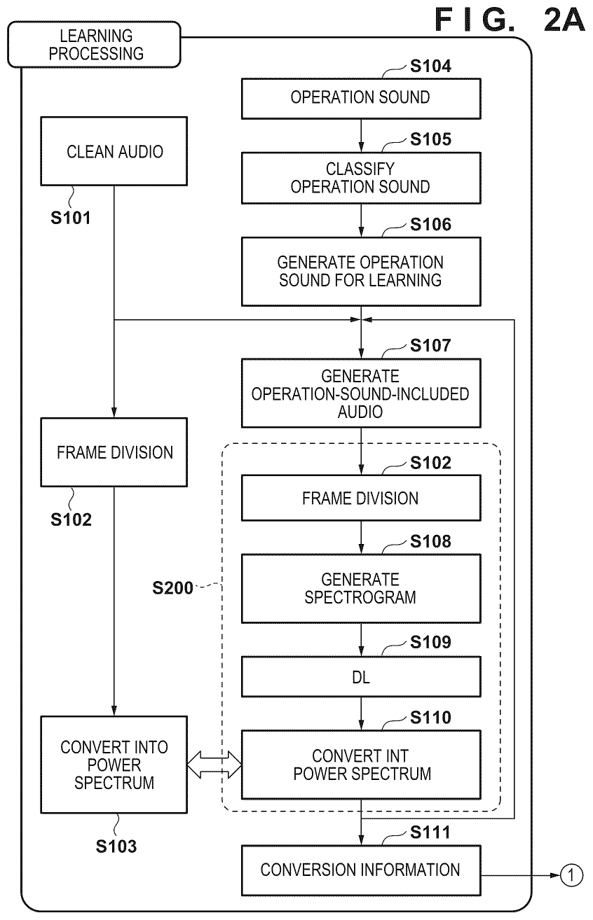

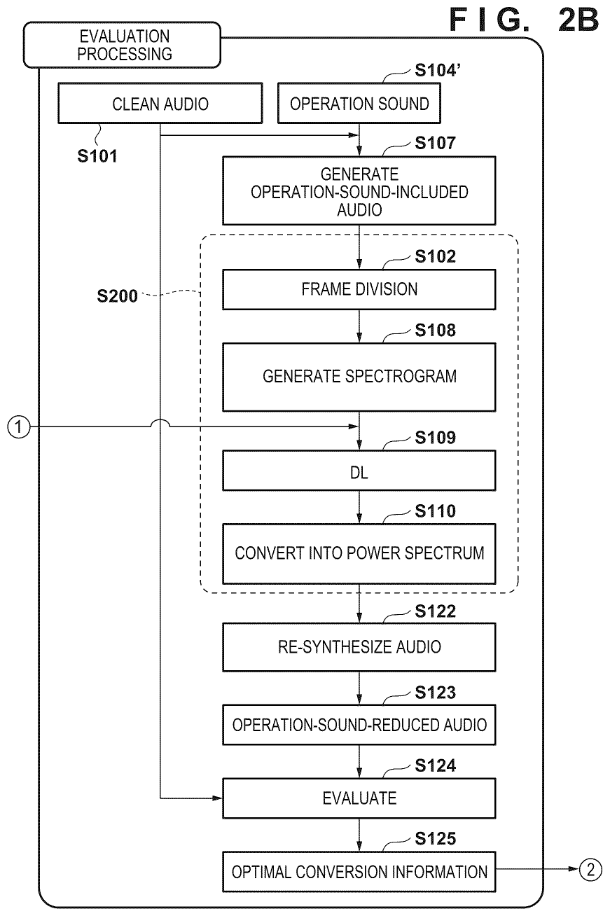

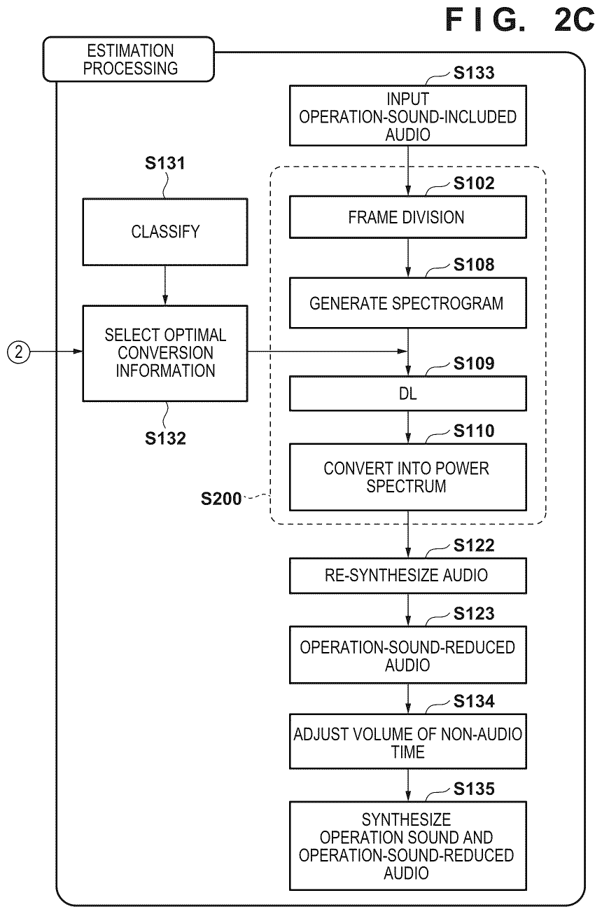

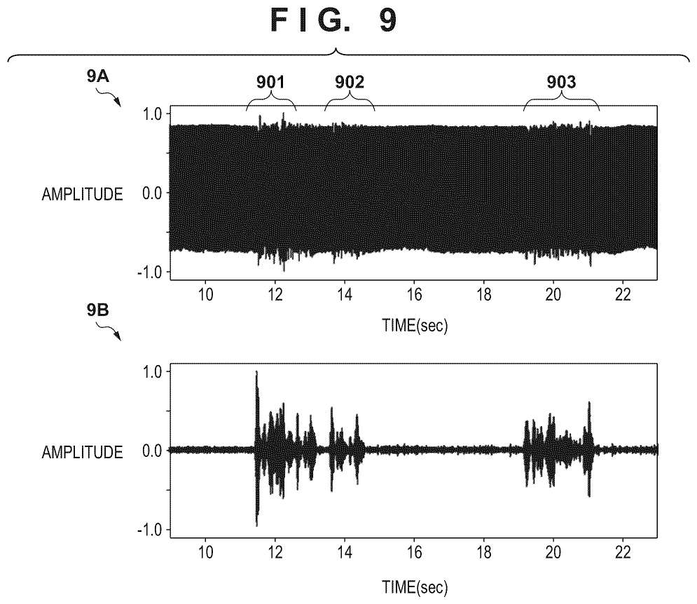

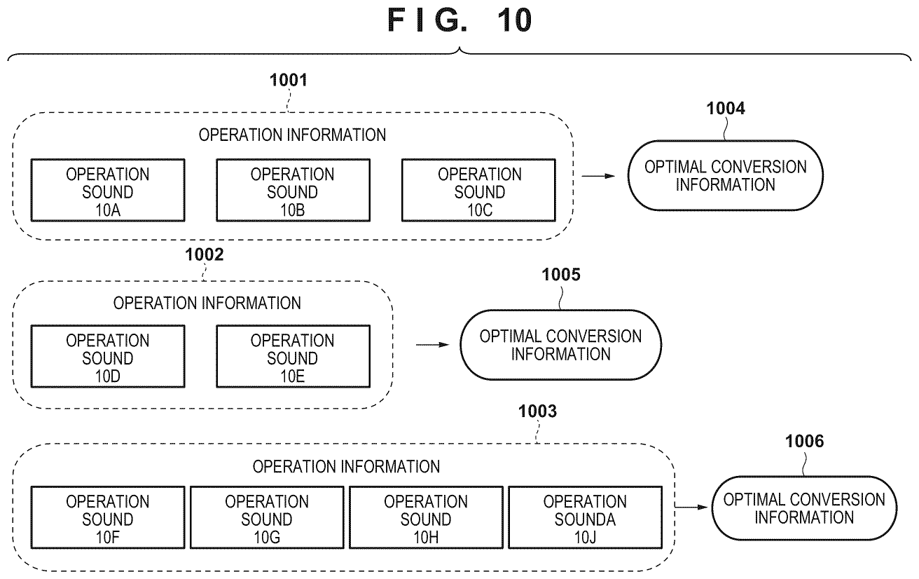

The description will return to that of FIG. 2C; in step S133, the operation-sound-included audio is inputted. The operation-sound-included audio of this step is the operation-sound-included audio which has been collected by the microphones 25 and in which the operation sound of the magnetic resonance imaging apparatus and the audio of the subject are overlapped. Here, 9A of FIG. 9 is a diagram illustrating a signal of the operation-sound-included audio; the horizontal axis indicates time, and the vertical axis indicates amplitude in a normalized manner. The portions filled in black are the operation sound of the magnetic resonance imaging apparatus 1, and in the signal waveform, regions 901 to 903 in which the amplitude protrudes are portions corresponding to the audio of the subject P. The audio of the subject P is overlapped on the operation sound, and the state is such that it is difficult to hear the audio of the subject. In the estimation processing according to the present embodiment, processing for estimating audio for which the operation sound has been reduced in the operation-sound-included audio is performed.

In step S200, the estimation processing unit 40C extracts features of the inputted operation-sound-included audio. The content of the feature extraction processing is similar to that of the learning processing, and the feature extraction processing includes steps from operation-sound-included audio frame division (step S102) to power spectrum generation (step S110).

The estimation processing unit 40C extracts features of the operation-sound-included audio, using the conversion information obtained by the evaluation processing (step S200) and obtains the power spectrum (step S110).

In step S122, the estimation processing unit 40C performs inverse fast Fourier transform (inverse FFT) on the power spectrum obtained in step S110, restores the audio signal for each frame, performs audio re-synthesis in which the restored per-frame audio signals are connected, and, by audio re-synthesis, generates audio (operation-sound-reduced audio) for which the operation sound has been reduced in the operation-sound-included audio (step S123). 9B of FIG. 9 is a diagram illustrating a signal of the operation-sound-reduced audio; the horizontal axis indicates time, and the vertical axis indicates amplitude in a normalized manner. The portions of the operation sound filled in black in 9A of FIG. 9 has been reduced, and the signal of the regions corresponding to the audio of the subject P is clarified.

In step S134, the estimation processing unit 40C separates non-audio time (non-audio region) in which there is no audio of the subject P and audio time (audio region) in which there is audio, based on the signal waveform of the operation-sound-reduced audio and adjusts the volume of the non-audio time (non-audio region). Then, in step S135, the estimation processing unit 40C generates synthesized audio for which the volume-adjusted operation sound (step S134) and the operation-sound-reduced audio (step S123) have been synthesized. The estimation processing unit 40C causes the speaker 420 (audio output apparatus) to output the synthesized audio for which a signal indicating an audio region obtained based on the estimated audio (operation-sound-reduced audio: step S123) and a signal indicating a non-audio region obtained based on the operation-sound-included audio (step S133) have been synthesized.

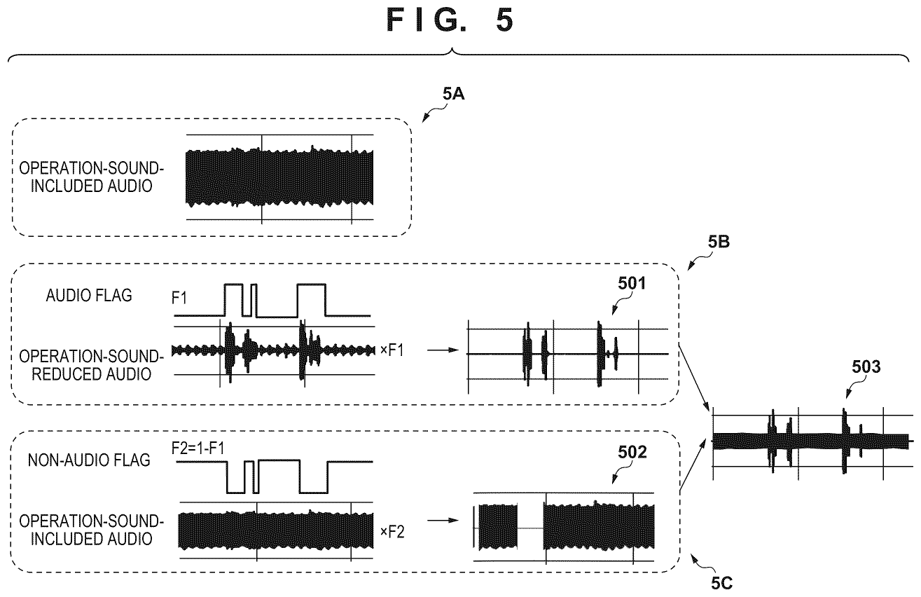

FIG. 5 is a diagram for schematically explaining volume adjustment and synthesized audio generation processing. 5A of FIG. 5 is a diagram illustrating a signal waveform of operation-sound-included audio.

In 5B of FIG. 5, F1 is an audio flag, which indicates audio time (audio region) in which there is audio in the operation-sound-reduced audio (step S123). The regions in which the pulse is raised indicate audio time (audio region) in which there is audio. Meanwhile, the regions in which the pulse has fallen indicate non-audio time (non-audio region) in which there is no audio. The estimation processing unit 40C obtains a signal waveform 501 by multiplying the signal of the operation-sound-reduced audio (step S123) by the audio flag F1. A small amount of signal is remaining in the non-audio time (non-audio region) in the signal of the operation-sound-reduced audio (step S123); however, by multiplying the operation-sound-reduced audio by the audio flag F1, the signal waveform 501, which indicates the audio time (audio region) for which the non-audio time (non-audio region) has been removed, is obtained.

In 5C of FIG. 5, F2 is a non-audio flag, which indicates non-audio time (non-audio region) in which there is no audio in the operation-sound-reduced audio (step S123). The regions in which the pulse is raised indicate non-audio time (non-audio region) in which there is no audio. Meanwhile, the regions in which the pulse has fallen indicate audio time (audio region) in which there is audio. The relationship between the non-audio flag F2 and the audio flag F1 is F2=−F1. The estimation processing unit 40C obtains a signal waveform 502 by multiplying the signal of the operation-sound-included audio (step S133) by the non-audio flag F2. By multiplying the operation-sound-included audio by the non-audio flag F2, the signal waveform 502, which indicates non-audio time (non-audio region) for which audio time (audio region) has been removed from the signal of the operation-sound-included audio, is obtained.

The estimation processing unit 40C synthesizes the signal waveform 501, which indicates audio time (audio region) and the signal waveform 502, which indicates non-audio time (non-audio region). The operation sound may be a clue indicating an examination state when a doctor is referencing an examination result. Therefore, it is preferable to generate operation-sound-reduced audio in which a small amount of operation sound is remaining and not completely remove it.

In the present embodiment, when synthesizing the signal waveform 501 and the signal waveform 502, the estimation processing unit 40C generates operation-sound-reduced audio 503 in which a small amount of operation sound is remaining.

A synthesis ratio between the signal waveform 501, which indicates audio time (audio region), and the signal waveform 502, which indicates non-audio time (non-audio region), can be arbitrarily set; for example, the estimation processing unit 40C may generate synthesized audio, using an emphasized signal for which the signal waveform 501, which indicates audio time (audio region), has been more emphasized than the signal waveform 502, which indicates non-audio time (non-audio region). Alternatively, the estimation processing unit 40C may generate synthesized audio, using a suppressed signal which the signal waveform 501, which indicates audio time (audio region), has been more suppressed than the signal waveform 502, which indicates non-audio time (non-audio region).

### (Variation)

In the first embodiment, a configuration in which a plurality of pieces of conversion information are evaluated using the signal distortion rate (SDR) as the evaluation information has been described; however, the evaluation information is not limited to the signal distortion rate (SDR), and for example, the plurality of pieces of conversion information may be evaluated using correlation information of waveforms and correlation information of power spectra for which Fourier transform has been performed on audio waveforms or using Perceptual Evaluation of Speech Quality (PESQ) described in International Telecommunication Union Standardization Sector (ITU-T) Recommendations.

### Second Embodiment

In the first embodiment, a configuration in which the conversion information is generated with the operation information as units of classification in the classification (step S105) of the operation sounds of the learning processing has been described. In the present embodiment, a configuration in which the operation information is divided according to the characteristics of the operation sounds or a plurality of pieces of operation information are grouped into one will be described.

### (Division Processing)

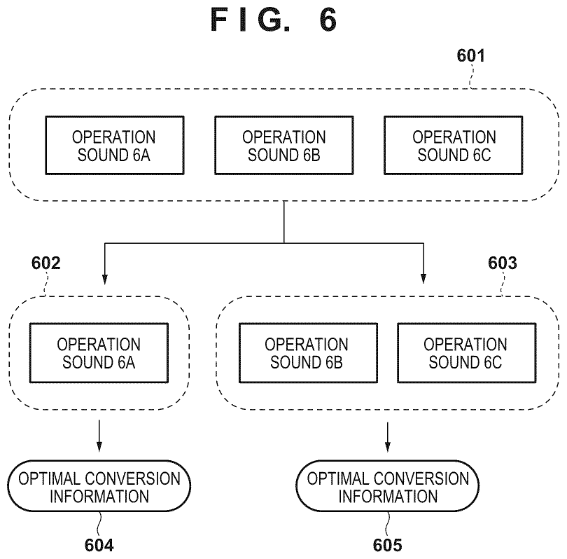

The learning processing unit 40A compares the characteristics of the plurality of operation sounds for learning, which have been classified based on the operation information, divides, from the class, the operation sounds for which at least some of the characteristics match, and performs the learning processing in units into which the operation sounds have been divided. FIG. 6 is a diagram schematically illustrating processing for dividing a class of operation sounds. In one piece of operation information 601, operation sounds 6A, 6B, and 6C have been recorded respectively for three different settings and are classified as operation sounds (6A to 6C) corresponding to the operation information 601. Here, the learning processing unit 40A may compare the characteristics of the operation sounds (6A to 6C) and group the operation sounds for which at least some of the characteristics of the operation sounds match into one. The characteristics of the operation sound include, for example, the period and the maximum amplitude of the operation sound.

The learning processing unit 40A compares the characteristics of the operation sounds 6A to 6C and groups the operation sounds whose characteristics of the operation sounds, such as the period and maximum amplitude of the operation sound, are the same into one. In the example illustrated in FIG. 6, the operation sound 6A whose characteristics are different from those of the operation sounds 6B and 6C becomes one grouped unit 602 and the operation sounds 6B and 6C whose characteristics are the same are classified into one grouped unit 603.

The learning processing unit 40A performs the learning processing for the division units 602 and 603, for which the operation information 601 has been divided into two, according to the processing flow of FIGS. 2A to 2C, and the evaluation processing unit 40B performs the evaluation processing based on the results of the learning processing. This makes it possible to obtain optimal conversion information 604 and 605 (learning results) as learning results that correspond to the division units 602 and 603, which are based on the characteristics of operation sounds.

In the estimation processing, an operation sound with which the match ratio is high is identified by comparison of at least a portion of the waveform of an operation sound, which has been collected by the microphones 25 of the magnetic resonance imaging apparatus 1, or the operation-sound-included audio and the waveform of the operation sounds for learning (6A to 6C). Regarding the comparison of signal waveforms, correlation information according to template matching can be used as will be described in the third embodiment. For example, if the match ratio is the highest with the waveform of the operation sound 6A among the operation sounds for learning, the collected operation sound or the operation-sound-included audio will be classified into the division unit 602 (step S131 of FIG. 2C). The estimation processing unit 40C obtains the optimal conversion information 604, which corresponds to the division unit 602, as a learning result and estimates audio for which the operation sound has been reduced in the operation-sound-included audio in which the operation sound and the audio of the subject are overlapped, using the obtained learning result.

There are cases where, even in one piece of operation information, the characteristics of the operation sound change depending on the setting; thus by dividing (finely dividing) the units of classification of operation sounds according to the characteristics of the operation sounds and performing the learning processing, it becomes possible to obtain a more accurate learning result (optimal conversion information).

### (Merge Processing)

The learning processing unit 40A compares the characteristics of the plurality of operation sounds for learning, which have been classified into respective ones of the plurality of pieces of operation information, and, if at least some characteristics match, performs the learning processing in units into which a plurality of operation sounds have been grouped.

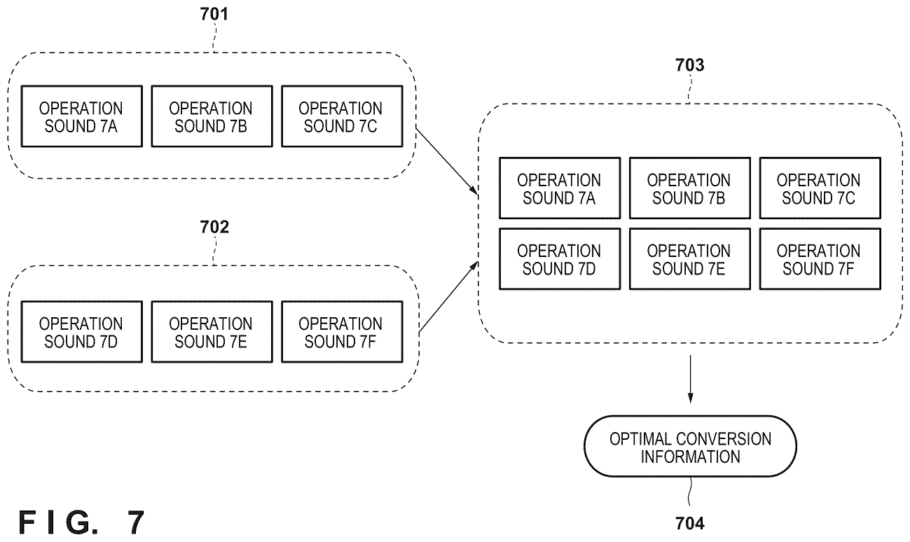

FIG. 7 is a diagram schematically illustrating processing (merge processing) for grouping classes of operation sounds corresponding to a plurality of pieces of operation information 701 and 702 into one. In one piece of operation information 701, operation sounds 7A, 7B, and 7C have been recorded respectively for three different settings and are classified as operation sounds (7A to 7C) corresponding to the operation information 701. In addition, in the operation information 702, which is different from the operation information 701, operation sounds 7D, 7E, and 7F have been recorded respectively for three different settings and are classified as operation sounds (7D to 7F) corresponding to the operation information 702.

The learning processing unit 40A compares the characteristics of the operation sounds 7A to 7F and, if at least some characteristics match among the characteristics of the operation sounds, such as the period and maximum amplitude of the operation sound, performs the learning processing collectively for a plurality of pieces of operation information 701 and 702. In the example illustrated in FIG. 7, if at least some characteristics among the characteristics of the operation sounds 7A to 7F match, the operation sounds 7A to 7F will be classified as one merged unit 703.

The learning processing unit 40A performs the learning processing for the merged unit 703, for which the operation information 701 and 702 have been grouped into one, according to the processing flow of FIGS. 2A to 2C, and the evaluation processing unit 40B performs the evaluation processing based on the result of the learning processing. This makes it possible to obtain optimal conversion information 704 as a learning result that corresponds to the merged unit 703, which is based on the characteristics of operation sounds.

In the estimation processing, an operation sound with which the match ratio is high is identified by comparison of at least a portion of the waveform of the operation sound, which has been collected by the microphones 25 of the magnetic resonance imaging apparatus 1, or the operation-sound-included audio and the waveform of the operation sounds for learning (7A to 7F . . . ). For example, if the match ratio is the highest with the waveform of the operation sound 7A among the operation sounds for learning, the collected operation sound or the operation-sound-included audio will be classified into the merged unit 703 (step S131 of FIG. 2C). The estimation processing unit 40C obtains the optimal conversion information 704, which corresponds to the merged unit 703, as a learning result and estimates audio for which the operation sound has been reduced in the operation-sound-included audio in which the operation sound and the audio of the subject are overlapped, using the obtained learning result. There are cases where, among the plurality of pieces of operation information, the characteristics of the operation sounds are the same depending on the setting; thus by grouping the operation sounds according to the characteristics of the operation sounds and performing learning processing, it becomes possible to reduce processing load in the learning processing.

### Third Embodiment

In the present embodiment, a method of selecting the optimal conversion information in the estimation processing will be described. First, the estimation processing unit 40C generates a template for which a portion of the signal waveform of an operation sound, which has been classified in the learning processing, has been cut out. During estimation, the class of an operation sound (or operation-sound-included audio), which has been collected by the microphones 25, is determined by comparing a portion of the signal waveform of the operation sound, which has been collected by the microphones 25, and the generated template (by performing template matching).

The estimation processing unit 40C selects optimal conversion information (learning result) according to the comparison of at least a portion of the waveform of the operation sound and the waveform of the operation-sound-included audio. The estimation processing unit 40C selects the optimal conversion information (learning result) according to correlation information, which has been obtained from the waveform of the operation sound and the waveform of the operation-sound-included audio. Specifically, the estimation processing unit 40C generates a template of the operation sound for learning, which has been classified in the learning processing, and, during estimation, obtains information on the correlation between the generated template and a portion of the signal waveform of the operation sound (or the operation-sound-included audio), which has been collected by the microphones 25. Then, the estimation processing unit 40C selects the optimal conversion information (learning result) of the class that includes the operation sound for which correlation information is the highest or the optimal conversion information (learning result) of the class whose average score of correlation information is the highest.

For example, the power spectrum, which has been obtained in the learning processing, may be used as the generated template. Alternatively, the operation sounds, which have been learned by deep learning, may be classified, and in the estimation processing, corresponding conversion information may be selected, based on the learning result, according to the class that the operation sound (or the operation-sound-included audio), which has been collected by the microphones 25, belongs.

In the first embodiment, a configuration in which the evaluation processing and the estimation processing are separately performed has been described; however, the present invention is not limited to this processing flow, and it is possible to perform the evaluation processing in parallel while executing the estimation processing.

The estimation processing unit 40C generates the operation-sound-included audio for evaluation from a signal of the operation sound for which a signal of an audio region of the subject has been removed from the operation-sound-included audio and the clean audio of the subject, which has been used in learning. The estimation processing unit 40C generates (step S123) the operation-sound-reduced audio for which the signal of the operation sound has been reduced in the operation-sound-included audio for evaluation, using the plurality of pieces of conversion information (step S111) for converting the operation-sound-included audio for learning into the clean audio. Then, the estimation processing unit 40C obtains (step S124) the evaluation information for evaluating the plurality of pieces of conversion information, using the operation-sound-reduced audio and the clean audio and selects (step S125), as a learning result, one piece of conversion information (optimal conversion information) from among the plurality of pieces of conversion information based on the evaluation information.

Specifically, similarly to the evaluation processing, during the estimation processing, the estimation processing unit 40C need only generate the operation-sound-included audio for evaluation (step S107) from a signal of a time for which it is thought that no audio is included in the operation-sound-included audio (step S133) (e.g., signal for which reference numerals 901 to 903 of 9A of FIG. 9 has been removed from the signal of the operation-sound-included audio) and the clean audio used in step S101 of the learning processing (step S101 of the evaluation processing), generate (step S123) the operation-sound-reduced audio, using the plurality of pieces of conversion information (step S111), which has been obtained in the learning processing, and select (steps S125 and S132), as the optimal conversion information, the evaluation information whose evaluation is the highest among the plurality of pieces of conversion information.

In addition, the classification (step S131) of operation information or operation sound and the selection (step S132) of optimal conversion information (learning result) during the estimation processing increases the computational load; thus, a processor dedicated to classification of the operation sound may be allocated. For example, the estimation processing unit 40C may select the learning result that corresponds to the operation information or the operation sound, using a first processor and perform the processing for estimating audio for which the operation sound has been reduced in the operation-sound-included audio, using a second processor, which is different from the first processor. According to the present embodiment, it is possible to improve the operation sound reduction performance without imposing a load on the computation of the operation-sound-reduced audio.

### Fourth Embodiment

In the present embodiment, a configuration that is related to an optimal conversion information selection timing in the estimation processing will be described. In the estimation processing, the optimal conversion information selection timing (step S132) is, for example, at the time of startup of the apparatus; however, regarding the selection timing, the optimal conversion information (learning result) may also be selected at any of the following timings, (a) to (c). For example, when any one of (a) to (c) applies, the estimation processing unit 40C obtains the optimal conversion information (learning result).

### (a) When Operation Information is Changed

When the operation information, which is inputted from the magnetic resonance imaging apparatus 1, is changed, the estimation processing unit 40C obtains the optimal conversion information (learning result) that corresponds to the new operation information. When, for example, the operation information, which is obtained from the magnetic resonance imaging apparatus 1, is changed from first operation information to second operation information, the estimation processing unit 40C obtains the optimal conversion information (learning result) that corresponds to the new operation information (second operation information) at a timing at which the second operation information has been newly obtained.

### (b) Change in Input Volume

The estimation processing unit 40C determines the level of the input volume of the operation sound (step S131) or the operation-sound-included audio (step S133) in a time series and, when the input volume is lower than a threshold volume for a certain amount of time and then the input volume rises, exceeding the threshold volume, obtains the optimal conversion information (learning result) that corresponds to the newly obtained operation sound.

### (c) Change in Peak Value or Standard Deviation of Input Volume

The estimation processing unit 40C obtains the level of input volume of the operation sound (step S131) or the operation-sound-included audio (step S133) in a time series at predetermined time intervals and obtains a change in a peak value or a standard deviation of input volume. When the obtained standard deviation or peak value changes, exceeding a reference threshold, the estimation processing unit 40C obtains the optimal conversion information (learning result) that corresponds to an operation sound that has been newly obtained after the reference threshold has been exceeded. According to the present embodiment, it is possible to obtain appropriate optimal conversion information (learning result) according to a change of the operation information, a change in the level of input volume, or a change in input volume in a time series and perform estimation processing, and thus it is possible to achieve improvement in estimation accuracy.

### Fifth Embodiment

In the present embodiment, a configuration that relates to the generation (step S107) of the operation-sound-included audio for learning in the learning processing will be described. In the first embodiment, the method of generating the operation-sound-included audio for learning by synthesizing the operation sound for learning (step S106) and the clean audio (step S101), which have been obtained in advance, has been described.

However, the operation sound of the magnetic resonance imaging apparatus 1 may change depending on the sound reflection, the temperature, and the difference between models; thus, unless learning is performed using many operation sounds, cases where the operation sound reduction performance is affected may occur. Therefore, in the present embodiment, a configuration in which a new operation sound S₀ is generated with the following Equation 3, using operation sounds for learning Sₖ (k=1 to N), which have been obtained in advance, will be described.

The learning processing unit 40A generates a new operation sound by summing products of existing operation sounds for learning and coefficients, according to the following Equation 3. The learning processing unit 40A may add the newly generated operation sound to the existing operation sounds for learning and perform the learning processing or may additionally perform the learning processing for the newly generated operation sound.

$${S}_{0} ( t ) = \sum {α}_{i} \times {S}_{i} ( t ) \qquad [ EQUATION 3 ]$$

Here, i is M arbitrary integers from 1 to N that do not overlap, and αᵢ is a coefficient. For example, a random number that satisfies Σαi=1 may be used.

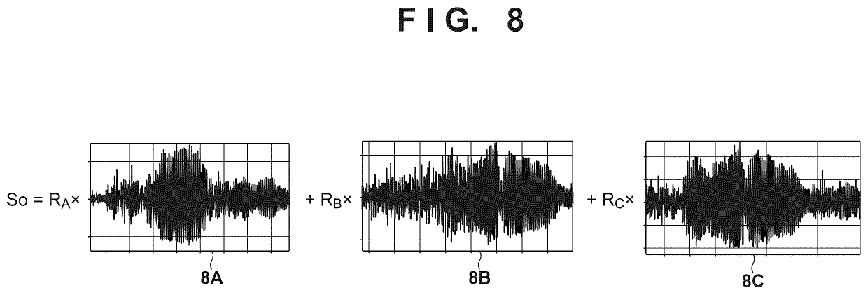

FIG. 8 is a diagram schematically illustrating a new operation sound S₀(t) generated using a random number. In FIG. 8, reference numerals 8A to 8C indicate the existing operation sounds for learning, and R_{A}, R_{B}, and R_{C}* indicate coefficients (random numbers). In the operation sounds 8A to 8C, the horizontal axis indicates time, and the vertical axis indicates amplitude in a normalized manner. When performing the learning processing, the learning processing unit 40A generates a new operation sound S₀ by summing products of existing operation sounds for learning 8A to 8C and coefficients R_{A}, R_{B}, and R_{C}.

An infinite number of new operation sounds S₀ can be generated by changing the integer i and the coefficient αᵢ; thus, it is particularly useful for when the amount of operation sound data is small.

### Sixth Embodiment

In the present embodiment, a configuration in which a new operation sound is added in the learning processing will be described. When the template matching correlation information, which has been described in the third embodiment, and the evaluation information (signal distortion rate (SDR)) in the estimation processing are smaller than a predetermined reference value or when the operation sound has not been sufficiently removed in the operation-sound-reduced audio (step S123) (when the operation sound of a certain level or higher is remaining), there is a possibility that the operation sound has not been learned. In such cases, the learning processing unit 40A records a new operation sound, adds it to a class as a new operation sound (step S105), and performs new learning.

For example, if the operation information of an operation sound that has not been learned (new operation sound) is the same as the existing operation information, which has been learned, and individual settings, such as imaging conditions, are different, the operation sound can be added to operation sounds that are classified based on the existing operation information. For example, as illustrated in FIG. 3, a configuration may be taken so as to, if the operation information is in common, and the settings of the new operation sound are different from the settings of the existing operation sounds 3A, 3B, and 3C in individual settings, such as imaging conditions, add, as an operation sound 3D, the operation sound that has not been learned (new operation sound) to the operation sounds (3A to 3C) that are classified based on the existing operation information, and perform the learning processing.

In addition, a configuration may be taken so as to obtain the correlation information of signal waveforms between the existing operation sounds, which have been learned, and the operation sound that has not been learned (new operation sound), add the operation sound that has not been learned (new operation sound) to the class that includes the existing operation sound whose correlation information is the highest among the learned operation sounds, and perform the learning processing.

In addition, a configuration may be taken so as to, when the operation information is different from the existing operation information, which has been learned, or when the correlation information with the existing operation sounds, which have been learned, is lower than a predetermined reference correlation value, not add the operation sound to the existing class and newly add the operation sound as an operation sound that is based on new operation information. According to the present embodiment, the learning processing need only be performed limitedly for the operation information to which the operation sound that has not been learned has been added; thus, efficient learning processing is possible.

### Seventh Embodiment

In the present embodiment, a configuration in which a computation model is changed according to the computational capabilities or processing load state of the processor in the console 400 will be described. As described in the first embodiment, there are various types of models that are used in deep learning. Even in a convolution-based deep learning computation model (R-CED model), the number of pieces of calculated conversion information may change depending on the number of layers and the number of filters. The operation sound removal performance increases as the number of pieces of conversion information increases; however, the processing time it takes for computation may also increase. The computation time may also increase with an increase in the data sampling frequency. Therefore, it is preferable to select a computation model and computation conditions according to the computational capabilities and processing state of the processor.

The learning processing unit 40A, the evaluation processing unit 40B, and the estimation processing unit 40C of the present embodiment can select a computation model or a computation condition to be used in the respective processes according to the state of the processing load of the processor.

FIG. 11 is a diagram illustrating a flow of processing in a seventh embodiment. In FIG. 11, the performer of the processing is described to be the estimation processing unit 40C; it can be similar for when the learning processing unit 40A and the evaluation processing unit 40B select a computation model to be used in the respective processes.

In step S1100, the estimation processing unit 40C obtains load information of the processor. Here, load information is information indicating the state of the load on the processor and includes, for example, a processor usage rate. In addition, the number of cores, the number of clocks, and the like may be used in combination as information indicating the computational capabilities of the processor.

In step S1110, the estimation processing unit 40C determines whether the load that has been obtained in step S1100 exceeds a load threshold. If the load on the processor does not exceed the load threshold (YES in step S1110), the processing proceeds to step S1120.

In step S1120, the estimation processing unit 40C selects the computation model to be used in the estimation processing. Here, a typical computation model (first computation model) is a computation model that is configured by a predetermined number (N) of layers and a predetermined number (F) of filters.

In step S1130, the estimation processing unit 40C performs the estimation processing, which has been described in FIGS. 2A to 2B, using the typical computation model (first computation model), which has been selected in step S1120.

Meanwhile, if the load exceeds the load threshold in the determination of step S1110 (NO in step S1110), the processing proceeds to step S1140.

In step S1140, the estimation processing unit 40C selects the computation model to be used in the estimation processing. Here, a computation model for load reduction (second computation model) is a computation model that is configured such that the computational load is lower than (e.g., the number of layers and the number of filters are reduced from those of) the typical computation model (first computation model: step S1130). In addition, the computation condition may be changed such that the data sampling frequency is lower than that of the typical computation model (first computation model).

Then, in step S1130, the estimation processing unit 40C performs the estimation processing, which has been described in FIGS. 2A to 2C, using the computation model for load reduction (the second computation model), which has been selected in step S1140. An example of the processing for changing the computation model has been described in FIG. 11; however, the computation condition for when the first computation model is used and the computation condition for when the second computation model is used may be changed together. According to the present embodiment, it is possible to select a computation model or a computation condition according to the load state of the processor and perform processing using the selected computation model.

According to the techniques disclosed according to each of the embodiments, it is possible to reduce the operation sound in the operation-sound-included audio in which the operation sound and the audio of the subject are overlapped.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-200509, filed Dec. 15, 2022, which is hereby incorporated by reference herein in its entirety.

What is claimed is:

1. An information processing apparatus comprising:
a selection unit configured to select a learning result that corresponds to operation information or an operation sound of a magnetic resonance imaging apparatus; and
an estimation unit configured to estimate audio for which the operation sound has been reduced in operation-sound-included audio in which the operation sound and audio of a subject are overlapped, using the learning result.

2. The information processing apparatus according to claim 1, wherein
the selection unit selects the learning result by comparing at least a portion of a waveform of the operation sound and a waveform of the operation-sound-included audio.

3. The information processing apparatus according to claim 2, wherein
the selection unit selects the learning result based on correlation information obtained from the waveform of the operation sound and the waveform of the operation-sound-included audio.

4. The information processing apparatus according to claim 1, wherein
in a case where operation information obtained from the magnetic resonance imaging apparatus has been changed, the selection unit obtains a learning result that corresponds to new operation information.

5. The information processing apparatus according to claim 1, wherein
the selection unit determines a level of an input volume of the operation sound or the operation-sound-included audio in a time series and, in a case where the input volume is smaller than a threshold volume for a certain amount of time and the input volume rises, exceeding the threshold volume, obtains a learning result that corresponds to a newly obtained operation sound.

6. The information processing apparatus according to claim 1, wherein
the selection unit obtains a level of an input volume of the operation sound or the operation-sound-included audio at predetermined time intervals and, in a case where a peak value or a standard deviation of the input volume exceeds a reference threshold, obtains a learning result that corresponds to a newly obtained operation sound.

7. The information processing apparatus according to claim 1, wherein
the estimation unit
causes an audio output unit to output synthesized audio for which a signal indicating an audio region obtained based on the estimated audio and a signal indicating a non-audio region obtained based on the operation-sound-included audio have been synthesized.

8. The information processing apparatus according to claim 7, wherein
the estimation unit generates the synthesized audio using an emphasized signal for which the signal indicating the audio region has been emphasized compared to the signal indicating the non-audio region or a suppressed signal for which the signal indicating the non-audio region has been suppressed compared to the signal indicating the audio region.

9. The information processing apparatus according to claim 1, wherein
the estimation unit
generates operation-sound-included audio for evaluation from a signal of an operation sound for which a signal of an audio region of the subject has been removed from the operation-sound-included audio and clean audio of the subject used for the learning result,
generates operation-sound-reduced audio for which the signal of the operation sound has been reduced in the operation-sound-included audio for evaluation, using a plurality of pieces of conversion information for converting operation-sound-included audio for learning into the clean audio,
obtains evaluation information for evaluating the plurality of pieces of conversion information, using the operation-sound-reduced audio and the clean audio, and
selects, as the learning result, one piece of conversion information from the plurality of pieces of conversion information based on the evaluation information.

10. The information processing apparatus according to claim 1, further comprising
a learning processing unit configured to perform learning processing for obtaining the learning result, using operation-sound-included audio for learning generated by overlapping an operation sound for learning and clean audio of a subject, which have been obtained in advance, wherein
the learning processing unit
generates a new operation sound by summing products of operation sounds for learning and coefficients, adds the generated new operation sound to the operation sound for learning, and performs the learning processing.

11. The information processing apparatus according to claim 10, wherein
in a case where operation information of an operation sound that has not been learned is the same as learned operation information and an imaging condition setting is different from that of an operation sound that has been classified based on the operation information, the learning processing unit adds the operation sound that has not been learned into a class that is based on the operation information and performs the learning processing.

12. The information processing apparatus according to claim 11, wherein
the learning processing unit obtains correlation information of a waveform of a learned operation sound and a waveform of an operation sound that has not been learned, adds the operation sound that has not been learned into a class that includes the learned operation sound whose correlation information is the highest, and performs the learning processing.

13. The information processing apparatus according to claim 12, wherein
in a case where the operation information of the operation sound that has not been learned is different from the learned operation information or in a case where the correlation information is lower than a predetermined reference correlation value, the learning processing unit
adds, as an operation sound that is based on new operation information, the operation sound that has not been learned and performs the learning processing.

14. The information processing apparatus according to claim 10, wherein
the learning processing unit compares characteristics of a plurality of operation sounds that are classified based on the operation information, separates, from the classified plurality of operation sounds, operation sounds for which at least some of the characteristics match, and performs the learning processing in separated units.

15. The information processing apparatus according to claim 10, wherein
the learning processing unit compares characteristics of a plurality of operation sounds that are classified into a respective one of a plurality of pieces of operation information and, in a case where operation sounds for which at least some of the characteristics match, performs the learning processing in units into which the plurality of operation sounds have been grouped.

16. The information processing apparatus according to claim 1, wherein
the estimation unit
includes a first computation model for performing the estimation and a second computation model configured so as to be lower in computational load than the first computation model,
in a case where a processing load of a processor does not exceed a load threshold, selects the first computation model and performs the estimation, and
in a case where the processing load of the processor exceeds the load threshold, selects the second computation model and performs the estimation.

17. The information processing apparatus according to claim 1, wherein
the selection unit performs the selection, using a first processor, and the estimation unit performs the estimation, using a second processor different from the first processor.

18. A magnetic resonance imaging apparatus comprising:
a sound collecting unit configured to collect operation-sound-included audio in which an operation sound and audio of a subject are overlapped;
a selection unit configured to select a learning result that corresponds to operation information or the operation sound;
an estimation unit configured to estimate audio for which the operation sound has been reduced in the operation-sound-included audio, using the learning result.

19. An information processing method comprising:
selecting a learning result that corresponds to operation information or an operation sound of a magnetic resonance imaging apparatus; and
estimating audio for which the operation sound has been reduced in operation-sound-included audio in which the operation sound and audio of a subject are overlapped, using the learning result.

20. A non-transitory computer-readable storage medium storing a program for causing a computer to execute the method according to claim 19.
